(19) United States
(12) Patent Application Publication
(10) Pub. No.: US 2025/0056760 A1
(43) Pub. Date: Feb. 13, 2025

(54) HEAT DISSIPATION MODULE AND ELECTRONIC DEVICE INCLUDING THE SAME

(71) Applicant: Samsung Display Co., Ltd., Yongin-Si (KR)

(72) Inventors: Jun Hee SON, Yongin-si (KR); Haeng Won PARK, Yongin-si (KR); Hyun Joon OH, Yongin-si (KR); Jee Na LEE, Yongin-si (KR)

(21) Appl. No.: 18/666,580

(22) Filed: May 16, 2024

(30) Foreign Application Priority Data
Aug. 7, 2023 (KR) 10-2023-0103088

(51) Int. Cl. H05K 7/20

(52) U.S. Cl. CPC H05K 7/20272; H05K 7/20981

(57) ABSTRACT

Provided herein may be a heat dissipation module including a first planar component, a partition wall coupled to the first planer component and defining a first path having one side closed by the first planar component, the first path forming a closed loop, and working fluid disposed in the first path. The heat dissipation module and an electronic device including the heat dissipation module in accordance with embodiments may be improved in heat dissipation efficiency.

### CROSS-REFERENCE TO RELATED APPLICATION

The present application claims priority to Korean patent application number 10-2023-0103088 filed on Aug. 7, 2023, the entire disclosure of which is incorporated herein in its entirety by reference.

### BACKGROUND

### 1. Field of Inventive Concept

Various embodiments of the present disclosure relate to a heat dissipation module and an electronic device including the heat dissipation module.

### 2. Description of Related Art

With the development of information technology, the importance of a display device, which is a connection medium between a user and information, has been emphasized. Owing to the importance of display devices, the use of various kinds of display devices, such as a liquid crystal display device and an organic light-emitting display device, has increased.

Electronic devices including display devices may generate heat during an operating process thereof. The heat generated during the operation of electronic devices can potentially degrade the performance of the electronic devices and, in some cases, shorten the lifespan of the electron devices. Therefore, there is a need for solutions that can efficiently dissipate heat generated from the electronic devices.

### SUMMARY

Various embodiments of the present disclosure are directed to a heat dissipation module with improved heat dissipation efficiency, and an electronic device including the heat dissipation module.

An embodiment of the present disclosure may provide a heat dissipation module including: a first planar component; a partition wall coupled to the first planer component and defining a first path having one side closed by the first planer component, the first path forming a closed loop; and working fluid disposed in the first path.

The heat dissipation module in accordance with an embodiment may further include a second planar component coupled to the partition wall with the partition wall disposed between the first planar component and the second planar component, and defining a second path disposed between the partition wall and the second planar component. The second path may communicate with the outside of the heat dissipation module.

The first planar component may include a first surface, and the second planar component may include a second surface.

The partition wall may be disposed to be inclined with respect to the first surface and the second surface. The first path may have a width of a third dimension disposed adjacent to the first surface and may have a width of a fourth dimension less than the third dimension and disposed adjacent to the second surface. The second path may have a width of a fifth dimension adjacent to the first surface and may have a width of a sixth dimension greater than the fifth dimension and disposed adjacent to the second surface.

An inclined angle formed between the partition and the first surface in an area corresponding to the first path is an acute angle.

The partition wall may include at least two stepped portions. The first path may have a width of a seventh dimension disposed between the first surface and the second surface and the seventh dimension may be less than the third dimension and greater than the fourth dimension. The second path may have a width of an eighth dimension disposed between the first surface and the second surface and the eighth dimension may be greater than the fifth dimension and less than the sixth dimension.

The partition wall may include an opening in an area facing away from the first planar component and the second path may communicate with the outside of the heat dissipation module through the opening.

The first path may have a width of a first dimension and the second path may have a width of a second dimension less than the first dimension.

The partition wall may include one or more stepped portions. The first path may have a width of a third dimension disposed adjacent to the first surface and may have a width of a fourth dimension less than the third dimension and disposed adjacent to the second surface. The second path may have a width of a fifth dimension disposed adjacent to the first surface and may have a width of a sixth dimension less than the fifth dimension and disposed adjacent to the second surface.

The working fluid may include liquid and an air layer.

The volume of the liquid in the working fluid may be 20% or more and less than 100%.

The heat dissipation module may further include a second planar component coupled to the partition wall and defining a second path disposed between the partition wall and the second planar component. The second planar component may include a hole that exposes at least a portion of the second path.

An embodiment of the present disclosure may include an electronic device including: a display panel provided with a plurality of pixels arranged to display an image on a front surface of the display panel; and a heat dissipation module disposed on a rear surface of the display panel. The heat dissipation module may include: a first planar component facing the rear surface of the display panel; a partition wall coupled to the first planar component and defining a first path one side of which is closed by the first planar component, and a second path spaced apart from the first path and communicating with an outside of the dissipation module, the first path forming a closed loop; and working fluid disposed in the first path.

The electronic device may further include an adhesive component attached to the rear surface of the display panel, and configured to attach the rear surface of the display panel to the first planar component of the heat dissipation module.

The first planar component may include a first surface connected to the partition wall and the second planar component may include a second surface connected to the partition wall.

The partition wall may be disposed to be inclined with respect to the first surface and the second surface. The first path may have a width of a third dimension disposed adjacent to the first surface and has a width of a fourth dimension less than the third dimension and disposed adjacent to the second surface. The second path may have a width of a fifth dimension disposed adjacent to the first surface and has a width of a sixth dimension greater than the fifth dimension and disposed adjacent to the second surface.

The partition wall may include at least one stepped portions. The first path may have a width of a third dimension disposed adjacent to the first surface, and may have a width of a fourth dimension less than the third dimension and disposed adjacent to the second surface. The second path may have a width of a fifth dimension disposed adjacent to the first surface and may have a width of a sixth dimension greater than the fifth dimension and disposed adjacent to the second surface.

The partition wall may include an opening in an area facing away from the first planar surface and the opening connects the second path to the outside of the heat dissipation module.

The first path may have a width of a first dimension, and the second path may have a width of a second dimension less than the first dimension.

The electronic device may further include a second planar component facing the first planar component with the partition wall disposed between the first planar component and the second planar component. The second planar component may include a hole that exposes at least a portion of the second path.

### BRIEF DESCRIPTION OF THE DRAWINGS

FIG. 1 is a perspective view of an electronic device in accordance with embodiments of the present disclosure.

FIG. 2 is an exploded perspective view of the display device illustrated in FIG. 1.

FIG. 3 is a system block diagram of a display module in accordance with embodiments of the present disclosure.

FIG. 4 is an equivalent circuit diagram of a pixel in accordance with embodiments of the present disclosure.

FIG. 5 is a sectional view of the pixel of FIG. 4.

FIG. 6 is a system block diagram illustrating a display module and a heat dissipation module in accordance with embodiments of the present disclosure.

FIG. 7 is a perspective sectional view of a heat dissipation module in accordance with embodiments of the present disclosure.

FIG. 8 is a sectional view illustrating area X in an embodiment of the heat dissipation module of FIG. 7.

FIG. 9 is a diagram for describing the heat dissipation module with liquid injected thereinto.

FIG. 10 is a rear perspective view of the heat dissipation module in accordance with embodiments of the present disclosure.

FIG. 11 is a diagram for describing performance of heat dissipation in the heat dissipation module in accordance with embodiments of the present disclosure.

FIG. 12 is a sectional view illustrating area X in another embodiment of the heat dissipation module of FIG. 7.

FIG. 13 is a sectional view illustrating area X in another embodiment of the heat dissipation module of FIG. 7.

FIG. 14 is a sectional view illustrating area X in another embodiment of the heat dissipation module of FIG. 7.

FIG. 15 is a rear view of a heat dissipation module according to other embodiments of the present disclosure.

### DETAILED DESCRIPTION

Hereinafter, embodiments of the present inventive concept will be described in detail with reference to the attached drawings, such that those skilled in the art can easily implement the present inventive concept. The present disclosure may be implemented in various forms, and is not limited to the embodiments to be described herein below.

In the drawings, portions which are not related to the present disclosure will be omitted in order to explain the present disclosure more clearly. Reference should be made to the drawings, in which similar reference numerals are used throughout the different drawings to designate similar components. Therefore, the aforementioned reference numerals may be used in other drawings.

For reference, the size of each component and the thicknesses of lines illustrating the component are arbitrarily represented for the sake of explanation, and the present disclosure is not limited to what is illustrated in the drawings. In the drawings, the thicknesses of the components may be exaggerated to clearly depict multiple layers and areas.

Furthermore, the expression “being the same” may mean “being substantially the same”. In other words, the expression “being the same” may include a range that can be tolerated by those skilled in the art. The other expressions may also be expressions from which “substantially” has been omitted.

It will be understood that, although the terms “first”, “second”, etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element. In the present disclosure, the singular forms are intended to include the plural forms as well, unless the context clearly indicates otherwise.

The terms “under”, “below”, “above”, “upper”, and the like are used herein for explaining relationship between one or more components illustrated in the drawings. These terms may be relative terms describing the positions of components in the drawings, but the positions of components are not limited thereto.

Unless otherwise defined, all terms (including technical and scientific terms) used herein have the same meaning as commonly understood by one of ordinary skill in the art to which this inventive concept belongs. Furthermore, terms as defined in a commonly used dictionary should be construed as having the same meaning as in an associated technical context, and unless defined apparently in the description, the terms are not ideally or excessively construed as having formal meaning.

It will be further understood that the terms “comprise”, “include”, “have”, etc. when used in this specification, specify the presence of stated features, integers, steps, operations, elements, components, and/or combinations of them but do not preclude the presence or addition of one or more other features, integers, steps, operations, elements, components, and/or combinations thereof.

Embodiments of the present disclosure will hereinafter be described in detail with reference to the accompanying drawings.

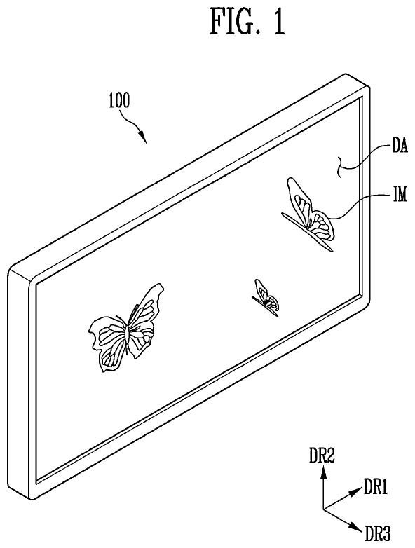

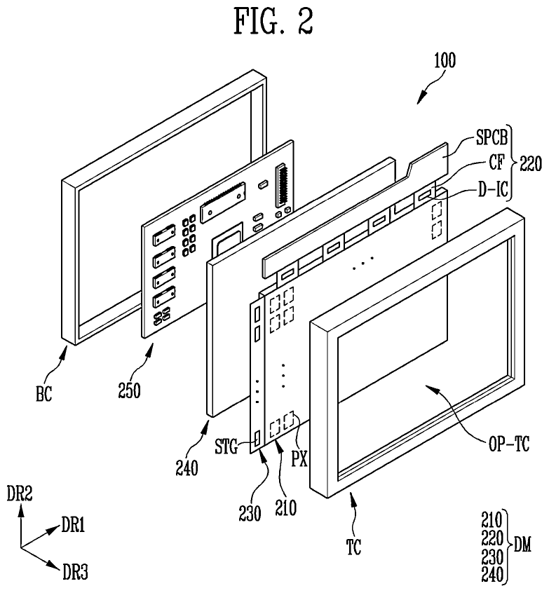

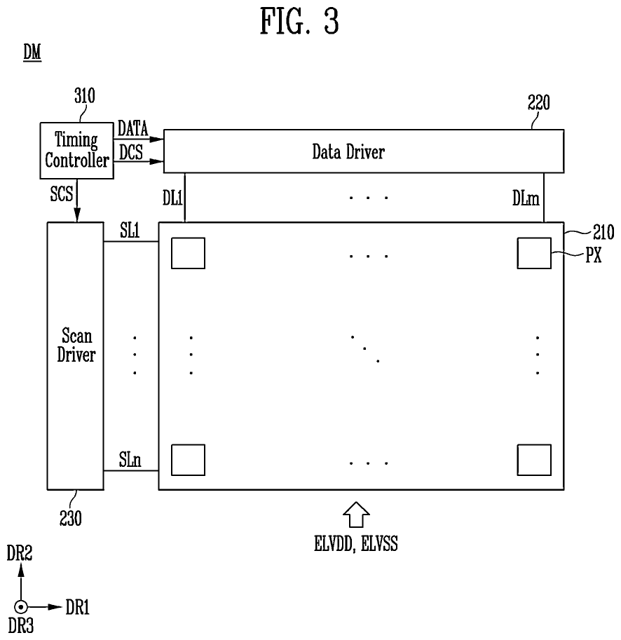

FIG. 1 is a perspective view of an electronic device 100 in accordance with embodiments of the present disclosure. FIG. 2 is an exploded perspective view of the electronic device 100 illustrated in FIG. 1. FIG. 3 is a system block diagram of a display module DM in accordance with embodiments of the present disclosure.

The electronic device 100 in accordance with embodiments of the present disclosure may include a top cover TC, a display panel 210, a data driver 220, a scan driver 230, a heat dissipation module 240, a driving circuit substrate 250, a bottom cover BC, and so on.

The bottom cover BC, the driving circuit substrate 250, and the heat dissipation module 240, the display panel 210, and the top cover TC may overlap each other in one direction (e.g., a third direction DR3), and may be disposed in the electronic device 100.

The display panel 210, the data driver 220, and the scan driver 230 may form the display module DM. In an embodiment, at least some components (e.g., the timing controller 310) disposed on the driving circuit substrate 250 may form the display module DM.

The electronic device 100 may provide information about an image IM to a user of the electronic device 100 through the display area DA. As an example of the image IM, a butterfly is illustrated.

The top cover TC may be configured to protect the display panel 210. The top cover TC may include a cover opening OP-TC. The cover opening OP-TC may expose a front surface of the display panel 210, thus allowing the display area DA to be exposed to the outside.

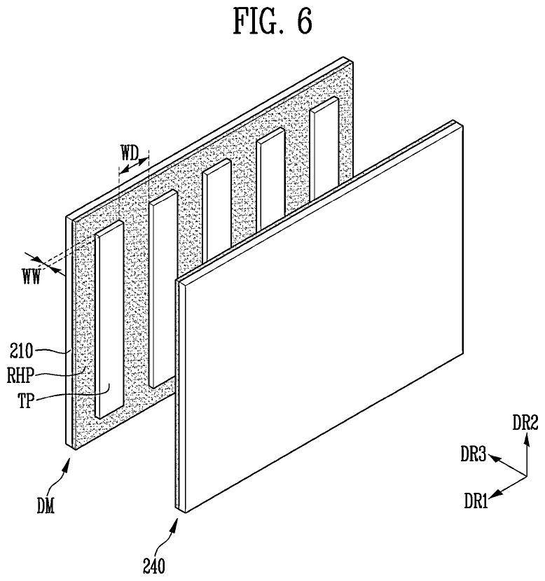

The heat dissipation module 240 may be configured to dissipate heat generated from the display module DM, the driving circuit substrate 250, and the like to the outside. For example, the heat dissipation module 240 may be configured to dissipate heat generated from the display panel 210, the data driver 220, the driving circuit substrate 250, and the like to the outside. Characteristics and configurations of the heat dissipation module 240 in accordance with embodiments of the present disclosure will be described in more detail with reference to FIG. 6 and the following figures.

The driving circuit substrate 250 may include circuit components such as the timing controller 310. In an embodiment, the timing controller 310, along with at least some components of the data driver 220, may be formed in a single integrated circuit. In the following, an example is given where the timing controller 310 and the data driver 220 are mounted in the electronic device 100 as separate circuit components, but embodiments of the present disclosure are not limited thereto. An additional power generation circuit (not illustrated) for generating various constant voltages supplied to the display module DM may be mounted on the driving circuit substrate 250. The power generation circuit may be implemented, for example, using a power management integrated circuit (PMIC).

The bottom cover BC may be configured to cover the display panel 210, the heat dissipation module 240, and the driving circuit substrate 250, and the like. The bottom cover BC may protect the aforementioned components from external impacts or contaminants.

The display module DM in accordance with embodiments of the present disclosure may include the display panel 210, the data driver 220, the scan driver 230, and so on.

A plurality of pixels PX are disposed in the display panel 210. A plurality of data lines DL1, . . . , and DLm (where m is an integer of 2 or more), a plurality of scan lines SL1, SL2, . . . , and SLn (where n is an integer of 2 or more), and so on, which are electrically connected to the plurality of pixels PA, may be disposed in the display panel 210. One or more power voltage lines configured to apply power voltages (e.g., a first power voltage ELVDD, a second power voltage ELVSS, and the like) to the plurality of pixels PX may be disposed in the display panel 210.

The display panel 210 may include a display area DA in which the plurality of pixels PX are disposed, and a non-display area positioned in a peripheral area of the display area DA (e.g., an edge area of the display area DA).

Although the display panel 210 may be formed to be flat (for example, evenly flat), embodiments of the present disclosure are not limited thereto. For example, the display panel 210 may include a curved surface portion (not illustrated) formed on each of left and right ends thereof. The curved surface portion may have a constant curvature or a variable curvature. In addition, the display panel 210 may be formed to be flexible so that the display panel 110 can be bent, curved, folded, or rolled.

Each of the pixels PX may include two or more sub-pixels. For example, the sub-pixels may be arranged in a matrix structure, or may be arranged in a PENTILE™ structure or the like. However, embodiments of the present disclosure are not limited to the foregoing structures.

The plurality of scan lines SL1 to SLn may be disposed in the display panel 210 and extend in a first direction DR1. The first direction DR1 may be, for example, a direction from the left to the right on the display panel 210. However, embodiments of the present disclosure are not limited to the foregoing structure.

The plurality of data lines DL1 to DLm may be disposed in the display panel 210 and extend in a second direction DR2. The second direction DR2 may be a direction different from the first direction DR1. For example, the second direction DR2 may be a direction perpendicular to the first direction DR1. The second direction DR2 may be, for example, a direction from an upper side to a lower side of the display panel 210.

The scan driver 230 may be configured to output scan signals with high-level voltage or low-level voltage to a plurality of scan lines SL1 to SLn in response to an scan driver control signal SCS received from the timing controller 310. For example, the scan driver control signal SCS may include a start signal instructing a frame to start, a horizontal synchronization signal for outputting a scan signal at a correct timing at which a data voltage is applied, and the like.

The scan driver 230 may include a plurality of stage circuits STG configured to supply scan signals to the plurality of scan lines SL1 to SLn.

The scan driver 230 may be implemented as an integrated circuit (e.g., a gate driver integrated circuit (GDIC)) formed separately from the display panel 210. The scan driver 230 may be formed along with the display panel 210, and may be formed in at least some areas on the non-display area of the display panel 210. In an embodiment, at least a portion of the scan driver 230 may be positioned to overlap the display area DA.

The data driver 220 may supply data voltages to the plurality of data lines DL1 to DLm. The data driver 220 may generate data voltages based on image data DATA and a data driver control signal DCS received from the timing controller 310, and output the generated data voltages to the plurality of data lines DL1 to DLm at correct timings. The data driver control signal DCS may include, for example, a source start pulse (SSP), a source shift clock (SSC), a source output enable signal (SOE), and the like.

The data driver 220 may include, for example, a source printed circuit board SPCB, a circuit film CF, and a data driving integrated circuit D-IC, and the like. The source printed circuit board SPCB may be configured to transmit various voltages to the data driving integrated circuit D-IC. The circuit film CF may connect between the source printed circuit board SPCB and the display panel 210. The data driving integrated circuit D-IC may be disposed on the circuit film CF.

The timing controller 310 may be configured to control the data driver 220 and the scan driver 230. The timing controller 310 may receive control signals (e.g., a synchronization signal, a data enable signal, and the like), a clock signal, and the like from external devices (e.g., a host, a set-top box, and the like). The timing controller 310 may generate and output control signals DCS and SCS to control the data driver 220, the scan driver 230, and the like, based on the received control signal and clock signal.

The timing controller 310 may be disposed in the electronic device 100 in the form of a logic or a processor. The timing controller 310 may include one or more registers.

The display module DM in accordance with embodiments of the present disclosure may be used not only as portable electronic devices such as a mobile phone, a smart phone, a tablet personal computer (a table PC), a smart watch, a watch phone, a mobile communication terminal, an electronic notebook, an electronic book, a portable multimedia player (PMP), a navigation device, and an ultra-mobile personal computer (UMPC), but also as display screens of various products such as a television, a notebook, a monitor, an advertisement panel, and an Internet of Tings (IoT). The display module DM in accordance with embodiments of the present disclosure may be used as a display screen for virtual reality (VR) devices, augmented reality (AR) devices, and the like.

In the case where the display module DM is used as a display screen for VR devices, AR devices, and the like, the electronic device 100 may be positioned remarkably close to the eyes of the user. In the case where the display module DM is used as a display screen for VR devices, AR devices, and the like, the electronic device 100 may have a high pixel (PX) density. As one method to increase the pixel (PX) density, the pixels PX may be formed on a silicon substrate. The technology of forming pixel circuits and associated light emitting elements (e.g., organic light emitting diodes (OLED)) on the silicon substrate may be referred to as OLEDOS (OLED on Silicon).

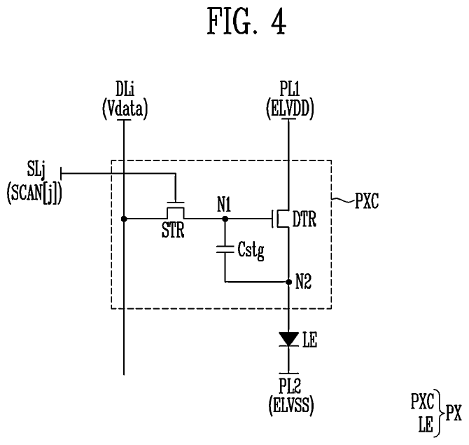

FIG. 4 is an equivalent circuit diagram of the pixel PX in accordance with embodiments of the present disclosure.

The pixel PX in accordance with embodiments of the present disclosure may include a pixel circuit PXC and a light emitting element LE.

The pixel circuit PXC in accordance with embodiments of the present disclosure may include one or more transistors and one or more capacitors. For example, referring to FIG. 4, the pixel circuit PXC may include a first transistor DTR, a second transistor STR, and a storage capacitor Cstg. However, the pixel circuit PXC in accordance with embodiments of the present disclosure are not limited to the aforementioned structure, and the pixel circuit PXC may include three or more transistors or may include two or more capacitors. Hereinafter, for the sake of explanation, an example will be described where the pixel circuit PXC includes two transistors and one capacitor.

The first transistor DTR may include a first electrode (e.g., either a source electrode or a drain electrode), a second electrode (e.g., a remaining one of the source electrode and the drain electrode), and a gate electrode. The first electrode (e.g., the drain electrode) of the first transistor DTR may be connected (e.g., electrically connected) to a first power line PL1. The second electrode (e.g., the source electrode) of the first transistor DTR may be connected (e.g., electrically connected) to a second node N2. The gate electrode of the first transistor DTR may be electrically connected (e.g., electrically connected) to a first node N1. Depending on the magnitude of voltage applied to the first node N1, the magnitude of current (e.g., driving current) flowing through the first transistor DTR may be adjusted. The first power voltage ELVDD may be applied to the first power supply line PL1. The first power voltage ELVDD may be a high-potential power voltage. The first transistor DTR may be referred to as a driving transistor.

The second transistor STR may be configured to switch electrical connection between the data line DLi (where i is an integer between 1 and m) and the first node N1 in response to a scan signal SCAN[j] (where j is an integer between 1 and n). The scan signal SCAN[j] may be applied to a scan line SLj. The scan signal SCAN[j] may have a turn-on level (e.g., either a high level or a low level) or a turn-off level (e.g., the other one of the high level and the low level). If the second transistor STR is turned on, a data voltage Vdata or a voltage corresponding to the data voltage Vdata may be applied to the first node N1. The second transistor STR may be referred to as a scan transistor.

The storage capacitor Cstg may be configured to maintain a difference in voltage between the first node N1 and the second node N2. The storage capacitor Cstg may include a first electrode connected (e.g., electrically connected) to the first node N1, and a second electrode connected (e.g., electrically connected) to the second node N2. The storage capacitor Cstg may be intentionally formed as a physical capacitor element rather than a parasitic capacitor.

The light emitting element LE may be connected between the second node N2 and a second power line PL2. The second power voltage ELVSS may be applied to the second power supply line PL2. The second power voltage ELVSS may be a low-potential power voltage. The light emitting element LE may include a first electrode (e.g., an anode electrode) connected (e.g., electrically connected) to the second node N2, and a second electrode (e.g., a cathode electrode) connected (e.g., electrically connected) to the second power line PL2. The light emitting element LE may further include an emission layer disposed between the anode electrode and the cathode electrode, and configured to emit light.

The emission layer may include high-molecular-weight or low-molecular-weight organic light emitting material. The emission layer may include inorganic light emitting material, or may include quantum dots. For example, the emission layer may include high-molecular-weight or low-molecular-weight organic light emitting material for emitting light in a certain wavelength band (e.g., a blue wavelength band, a green wavelength band, or a red wavelength band). However, embodiments of the present disclosure are not limited to the aforementioned example.

One or more transistors that form the pixel circuit PXC may include a P-type or N-type semiconductor layer. For example, at least one of the first and second transistors DTR and STR may be implemented as a field effect transistor (FET) including a P-channel metal oxide semiconductor (PMOS). For example, at least one of the first and second transistors DTR and STR may be implemented as a field effect transistor including an N-channel metal oxide semiconductor (NMOS).

Referring to FIG. 4, an example is given where each of the first and second transistors DTR and STR includes an N-channel metal oxide semiconductor. However, embodiments of the present disclosure are not limited to the foregoing structure. For example, at least one of the first and second transistors DTR and STR may be implemented as a field effect transistor including a P-channel metal oxide semiconductor (NMOS).

Transistors that form the pixel circuit PXC may include an amorphous silicon (a-Si) semiconductor, an oxide semiconductor, a low temperature polycrystalline silicon (LTPS) semiconductor, and so on. For example, some of two transistors that form the pixel circuit PXC may include a low temperature poly silicon semiconductor, and the other may include an oxide semiconductor.

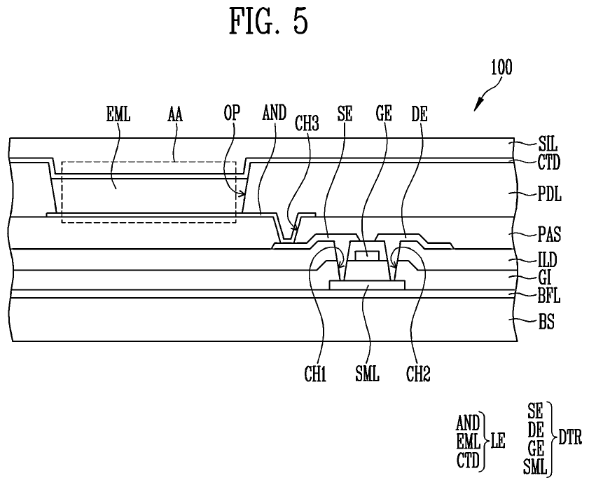

FIG. 5 is a sectional view of the pixel PX of FIG. 4.

The pixel PX or a display panel 210 (refer to FIG. 2) may include a base substrate BS, a buffer layer BFL, a semiconductor layer SML, a gate insulating layer GI, a gate electrode GE, an interlayer insulating layer ILD, a source electrode SE, a drain electrode DE, a passivation layer PAS, a pixel defining layer PDL, a light emitting element LE, an encapsulation layer SIL, and so one.

The buffer layer BFL may be disposed on one surface of the base substrate BS. The buffer layer BFL may be configured to prevent penetration or diffusion of impurities from the base substrate BS during a fabrication process. The buffer layer BFL may prevent impurities from diffusing into the semiconductor layer SML. Impurities may be drawn from the outside or may be generated by thermal decomposition of the base substrate BS. Impurities may include gas or natrium discharged from the base substrate BS. The buffer layer BFL may block water penetrated from the outside.

The semiconductor layer SML may be disposed on the buffer layer BFL. The semiconductor layer SML may include a polycrystalline silicon semiconductor, an amorphous silicon semiconductor, an oxide semiconductor, and so on. The semiconductor layer SML may include a channel area where electrons or holes can move, and a first ion-doped area (e.g., a source area) and a second ion-doped area (e.g., a drain area) with the channel area interposed therebetween.

The gate insulating layer GI may be disposed on the semiconductor layer SML. The gate insulating layer GI may cover the semiconductor layer SML. The gate insulating layer GI may include an organic layer and/or inorganic layer. The gate insulating layer GI may include a plurality of inorganic thin films. The inorganic thin films may include a silicon nitride layer, a silicon oxide layer, and the like.

The gate electrode GE of the first transistor DTR may be disposed on the gate insulating layer GI.

The interlayer insulating layer ILD may be disposed on the gate electrode GE. The interlayer insulating layer ILD may include an organic layer and/or inorganic layer. The interlayer insulating layer ILD may include a plurality of inorganic thin films. The inorganic thin films may include a silicon nitride layer, a silicon oxide layer, and the like. The first electrode DE (e.g., the drain electrode DE) and the second electrode SE (e.g., the source electrode SE) of the first transistor DTR may be disposed on the interlayer insulating layer ILD. The first electrode DE of the first transistor DTR may be connected (e.g., electrically connected) to the semiconductor layer SML of the first transistor DTR through a second contact hole CH2. The second electrode SE of the first transistor DTR may be connected (e.g., electrically connected) to the semiconductor layer SML of the first transistor DTR through a first contact hole CH1. The first contact hole CH1 may be formed by removing at least portions of the gate insulating layer GI and the interlayer insulating layer ILD. The second contact hole CH2 may be formed by removing at least portions of the gate insulating layer GI and the interlayer insulating layer ILD.

The passivation layer PAS may be disposed on the interlayer insulating layer ILD to cover the first electrode DE and the second electrode SE of the first transistor DTR. The passivation layer PAS may include an organic layer and/or inorganic layer. For example, the passivation layer PAS may include an organic layer to planarize an area over the first electrode DE and the second electrode SE.

The pixel defining layer PDL is disposed on the passivation layer PAS. The pixel defining layer PDL may define the opening OP by removing at least a portion thereof. The light emitting element LE may be formed in an active area AA corresponding to the opening OP. The active area AA may correspond to an emission area where light is emitted from the light emitting element LE.

The light emitting element LE may be disposed on the passivation layer PAS. The light emitting element LE may be implemented, for example, using an organic light emitting diode (OLED) including an organic emission layer. In an embodiment, the light emitting element LE may be implemented using an inorganic light emitting element including an inorganic emission layer. Hereinafter, for the sake of explanation, an example will be described where the light emitting element LE in accordance with an embodiment of the present disclosure includes an organic light emitting diode, but it should be noted that embodiments of the present disclosure are not limited thereto.

The anode electrode AND may be disposed on the passivation layer PAS. The anode electrode AND may be connected (e.g., electrically connected) to the second electrode SE of the first transistor DTR through a third contact hole CH3. The third contact hole CH3 may be formed in the passivation layer PAS. The anode electrode AND may have conductivity. The anode electrode AND may be either a pixel electrode or a positive electrode. The anode electrode AND may have light transmittance. In an embodiment where the anode electrode AND is a transparent electrode, the anode electrode AND may be made of transparent metal oxide such as indium tin oxide (ITO), indium zinc oxide (IZO), zinc oxide (ZnO), indium tin zinc oxide (ITZO), or the like. In an embodiment where the anode electrode AND is a transflective electrode or a reflective electrode, the anode electrode AND may include Ag, Mg, Al, Pt, Pd, Au, Ni, Nd, Ir, Cr, or a mixture of the aforementioned metals. The anode electrode AND may have a single-layer or multilayer structure made of transparent metal oxides or metals. For example, the anode electrode AND may have a single-layer structure including ITO, Ag, or a metallic mixture (e.g., a mixture of Ag and Mg), a double-layer structure of ITO/Mg or ITO/MgF, or a triple-layer structure of ITO/Ag/ITO, but embodiments of the present disclosure are not limited to the aforementioned embodiments.

The emission layer EML may be disposed on the anode electrode AND. In an embodiment, a first functional layer (not illustrated) may be interposed between the anode electrode AND and the emission layer EML. In an embodiment, an second functional layer (not illustrated) may be interposed between the emission layer EML and the cathode electrode CTD.

The first functional layer may be positioned on the anode electrode AND, and configured to inject and/or transport holes. The first functional layer may include at least one of a hole injection layer (not illustrated), a hole transport layer (not illustrated), and an electron blocking layer (not illustrated). The first functional layer may have, for example, a single layer formed of a single material, a single layer formed of a plurality of different materials, or a multilayer structure having a plurality of layers formed of a plurality of different materials.

The emission layer EML may have a single layer formed of a single material, a single layer formed of a plurality of different materials, or a multilayer structure having a plurality of layers formed of a plurality of different materials. The emission layer EML may be formed using various methods such as a vacuum deposition method, a spin coating method, a casting method, a Langmuir-Blodgett (LB) method, an inkjet printing method, a laser printing method, and a laser-induced thermal imaging (LITI) method. The emission layer EML is not limited to specific material, so long as it is material that is commonly used. For example, the emission layer EML may be formed of material that emits light in the red wavelength band, light in the green wavelength band, and/or light in the blue wavelength band, and may include fluorescent or phosphorescent material. Furthermore, the emission layer EML may include a host and a dopant.

The second functional layer may be positioned under the cathode electrode CTD, and configured to inject and/or transport electrons. The second functional layer may include an electron transport layer (not illustrated) and an electron injection layer (not illustrated), but is not limited thereto. The electron transport layer may have a structure including an electron transport layer and an electron injection layer that are successively stacked. Furthermore, the electron transport layer may have a single-layer structure with a mixture of two or more layers, but embodiments of the present disclosure are not limited thereto. The second functional layer may be formed using various methods such as a vacuum deposition method, a spin coating method, a casting method, an LB method, an inkjet printing method, a laser printing method, and a laser-induced thermal imaging (LITI) method.

The cathode electrode CTD may be disposed on the emission layer EML, and may be made of a metal or alloy with a low work function or an electrically conductive compound, or a mixture of the aforementioned materials. The cathode electrode CTD may be either a common electrode or a negative electrode. The cathode electrode CTD may be a transmissive electrode, a transflective electrode, or a reflective electrode. In the case where the cathode electrode CTD is a transmissive electrode, the cathode electrode CTD may include Li, Ca, LiF/Ca, LiF/Al, Al, Mg, Ag or a compound or mixture thereof (e.g., a mixture of Ag and Mg). The cathode electrode CTD may include an auxiliary electrode. The auxiliary electrode may include transparent metal oxide such as indium tin oxide (ITO), indium zinc oxide (IZO), zinc oxide (ZnO), or indium tin zinc oxide (ITZO). In the case where the cathode electrode CTD is a transflective electrode or reflective electrode, the cathode electrode CTD may include Ag, Mg, Al, Pt, Pd, Au, Ni, Nd, Ir, Cr, Li, Ca, LiF/Ca, LiF/Al or a compound or mixture thereof (e.g., a mixture of Ag and Mg). Alternatively, the cathode electrode CTD may include transparent metal oxide formed of material such as indium tin oxide (ITO), indium zinc oxide (IZO), zinc oxide (ZnO), or indium tin zinc oxide (ITZO).

In the case where the light emitting element LE is a top-emission-type light emitting element, the anode electrode AND may be a reflective electrode, and the cathode electrode CTD may be a transmissive electrode or a transflective electrode. In the case where the light emitting element LE is a bottom-emission-type light emitting element, the anode electrode AND may be a transmissive electrode or a transflective electrode, and the cathode electrode CTD may be a reflective electrode.

FIG. 6 is a perspective view of the display module DM and the heat dissipation module 240 in accordance with embodiments of the present disclosure.

A heat dissipation layer RHP may be disposed on a rear surface of the display panel 210 in accordance with embodiments of the present disclosure. For example, a front surface of the display panel 210 may be a surface of the display panel 210 on which images IM (refer to FIG. 1) can be displayed, and the rear surface of the display panel 210 may be a surface facing the front surface of the display panel 210, where images IM are not displayed.

The heat dissipation layer RHP may be configured to dissipate heat generated from the display module DM (e.g., the display panel 210). The heat dissipation layer RHP may have a heat radiation rate (or heat emissivity) of a certain value or more. For example, the heat radiation rate of the heat dissipation layer RHP may be 0.8 or more. The heat dissipation layer RHP may be a coated layer formed by applying heat-dissipating paint. The heat dissipation layer RHP may include, for example, ceramic composites. In embodiments of the present disclosure, the heat dissipation module 240 may further be disposed under the display module DM (e.g., the display panel 210) to enhance the heat dissipation of the display module DM. When the heat dissipation module 240 is disposed under the display module DM, the heat dissipation layer RHP disposed on the rear surface of the display panel 210 may be omitted.

An adhesive component TP may be disposed on the rear surface of the display panel 210. The adhesive component TP may attach the display module DM (e.g., the display panel 210) to the heat dissipation module 240 (for example, through adhesion). The adhesive component TP may have a certain thickness WW in the third direction DR3. The adhesive component TP may extend in the second direction DR2.

A plurality of adhesive components TP may be disposed on the rear surface of the display panel 210. The adhesive components TP may be disposed to be spaced apart from each other in the first direction DR1. For example, the adhesive components TP may be disposed to be spaced apart from each other with a certain distance WD. Each of the adhesive components TP may extend in the second direction DR2.

The adhesive component TP may include air hole. The air hole may be provided to absorb impacts exerted on the adhesive component TP. The adhesive component TP may be interposed between the display module DM (e.g., the display panel 210) and the heat dissipation module 240 to absorb external impacts. The adhesive component TP may be implemented, for example, using foam tape.

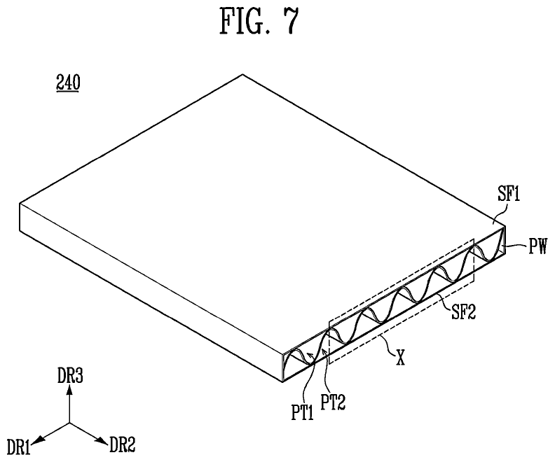

FIG. 7 is a perspective sectional view of the heat dissipation module 240 in accordance with embodiments of the present disclosure.

Referring to FIG. 7, the dissipation module 240 in accordance with embodiments of the present disclosure may include a first surface SF1 and a second surface SF2, and a partition wall PW disposed between the first surface SF1 and the second surface SF2.

The first surface SF1 may refer to a surface facing the display module DM. The first surface SF1 may be a surface that is attached to the adhesive component TP (refer to FIG. 6).

The second surface SF2 may refer to a surface disposed away from the display module DM and facing the first surface SF1.

The partition wall PW may include corrugations. The corrugations may form a first path PT1 and a second path PT2 that are isolated from each other. The first path PT1 may be formed between the partition wall PW and the first surface SF1. The second path PT2 may be formed between the partition wall PW and the second surface SF2.

The first path PT1 may be an area formed to receive fluid (e.g., liquid) for heat dissipation. The first path PT1 may include one or more closed loops. The fluid may include an air layer (e.g., bubble). Due to heat applied to at least a portion of the first path PT1, the volume of the air layer in the corresponding area may expand. Due to heat dissipated from a remaining portion of the first path PT1, the volume of the air layer in the corresponding area may contract. As a result of expansion and contraction, the fluid may vibrate. Heat is transferred through the fluid, so that heat dissipation can be performed in the heat dissipation module 240. The first path PT1 may be enclosed by the partition wall PW and the first surface SF1.

The second path PT2 may be an area exposed to the outside. The second path PT2 may be an area through which external air is inflowed into the heat dissipation module 240, or internal air is discharged out of the heat dissipation module 240. For example, the second path PT2 may be connected to the outside of the heat dissipation module 240 in the first direction DR1 and/or the second direction DR2. In an embodiment, the second path PT2 may be connected to the outside of the heat dissipation module 240 in the third direction DR3. The second path PT2 may be enclosed by the partition wall PW. In an embodiment, the second path PT2 may also be enclosed by the second surface SF2.

In an embodiment, the first surface SF1 and the partition wall PW may be formed integrally with each other. For example, the first surface SF1 and the partition wall PW may be formed integrally with each other in such a way that the first surface SF1 and the partition wall PW are successively formed using a 3-dimensional (3D) printing method. However, in embodiments of the present disclosure, the method of integrally forming the first surface SF1 and the partition wall PW is not limited to the 3D printing method, and the aforementioned example is merely illustrative.

In an embodiment, the first surface SF1 and the partition wall PW may be formed as separate components. For example, the partition wall PW may be attached (or coupled) to the first surface SF1 which has a planar shape, thus forming the heat dissipation module 240. In an embodiment, the second surface SF2 may be formed along with the first surface SF1 and the partition wall PW through the aforementioned 3D printing method. In an embodiment, the second surface SF2 may be separately prepared and be attached (or coupled) to the partition wall PW, thus forming the heat dissipation module 240.

Hereinafter, for the sake of explanation, an example will be described where the heat dissipation module 240 in accordance with an embodiment of the present disclosure includes the second surface SF2, but it should be noted that embodiments of the present disclosure are not limited thereto. Hereinafter, for the sake of explanation, an example will be described where the heat dissipation module 240 in accordance with an embodiment of the present disclosure has a structure such that the first surface SF1, the partition wall PW, and the second surface SF2 are formed separately from each other, but it should be noted that embodiments of the present disclosure are not limited thereto.

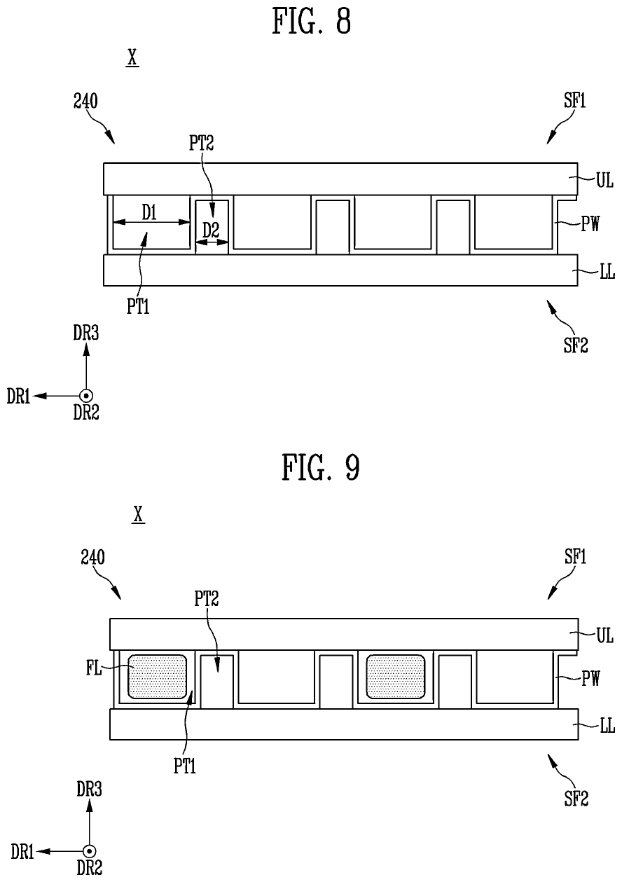

FIG. 8 is a sectional view illustrating area X in an embodiment of the heat dissipation module 240 of FIG. 7. FIG. 9 is a diagram for describing the heat dissipation module 240 with liquid FL injected thereinto.

Referring to FIG. 8, the heat dissipation module 240 in accordance with embodiments of the present disclosure may include a first planar component UL (e.g., a first plate-shaped member), a partition wall PW, and a second planar component LL (e.g., a second plate-shaped member).

The first planar component UL may include a first surface SF1. The first planar component UL may be connected (e.g., attached or coupled) to the partition wall PW on a surface thereof facing away from the first surface SF1. In an embodiment, the first planar component UL may include a high heat transfer material, for example, metal. In an another embodiment, the first planar component UL may include a polymer with thermal conductivity lower than that of metal (e.g., copper (Cu), gold (Au), etc.). For example, since substantial heat dissipation in the heat dissipation module 240 is performed by the liquid FL filled between the partition wall PW and the first planar component UL, the material for the first planar component UL may be selected from among materials with relatively lower thermal conductivity than the metal (e.g., polymers).

The second planar component LL may include a second surface SF2. The second planar component LL may be connected (e.g., attached or coupled) to the partition wall PW on a surface thereof facing away from the second surface SF2. In an embodiment, the second planar component LL may include a high heat transfer material, for example, metal. In another embodiment, the second planar component LL may include a polymer with thermal conductivity lower than that of metal (e.g., copper (Cu), gold (Au), etc.). For example, since substantial heat dissipation in the heat dissipation module 240 is performed by the liquid FL filled between the partition wall PW, the material for the second planar component LL may be selected from among materials with relatively lower thermal conductivity than the metal (e.g., polymers).

The first planar component UL may enhance the rigidity of the heat dissipation module 240. The second planar component LL may also enhance the rigidity of the heat dissipation module 240. The first planar component UL and the second planar component LL may also function as a chassis to prevent the display panel 210 (refer to FIG. 2) or the like from being damaged due to forces applied to the electronic device 100 (refer to FIG. 1). The first planar component UL and the second planar component LL may include, for example, material that has relatively low thermal conductivity and is capable of providing relatively high rigidity. The partition wall PW may form a first path PT1 and a second path PT2. Each of the first path PT1 and the second path PT2 may have a certain width. For example, each of the first path PT1 may have a uniform width of a first dimension D1. For example, the second path PT2 may have a uniform width of a second dimension D2.

The first dimension D1 is a dimension sufficient for allowing the liquid FL filled in the first path PT1 to move through a capillary phenomenon to transfer heat, and is not limited in dimension. The first dimension D1 may be determined and designed to vary depending on the type of liquid FL accommodated in the first path PT1.

The liquid FL may be, for example, water, Freon, methanol, or ethanol, but embodiments of the present disclosure are not limited thereto. The liquid FL and an air layer (e.g., bubbles) inside the liquid FL may be referred as working fluid.

In an embodiment, the first dimension D1 may be greater than the second dimension D2. For example, an increase in surface area of a portion of the first planar component UL that contacts the liquid FL may enhance the heat dissipation effect of the heat dissipation module 240. However, embodiments of the present disclosure are not limited to the aforementioned example. The first dimension D1 may be identical (or substantially identical) to the second dimension D2. In an embodiment, the first dimension D1 may be less than the second dimension D2.

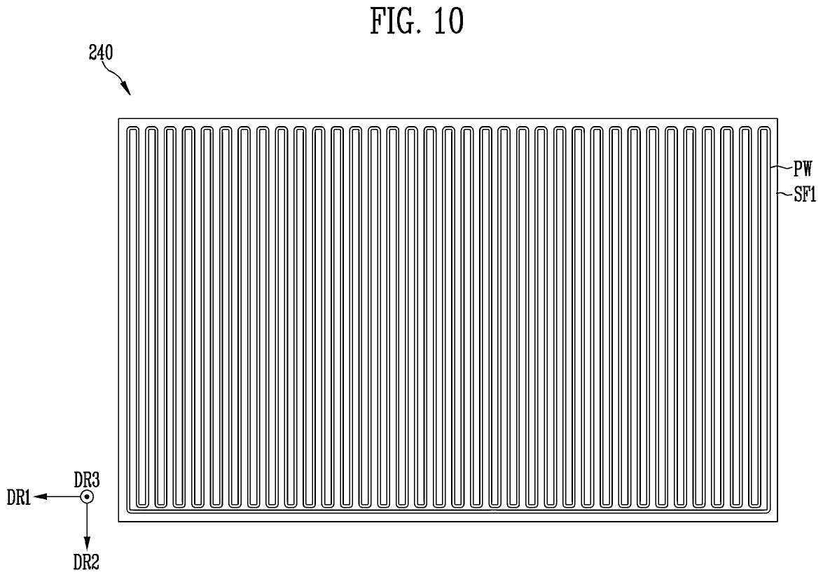

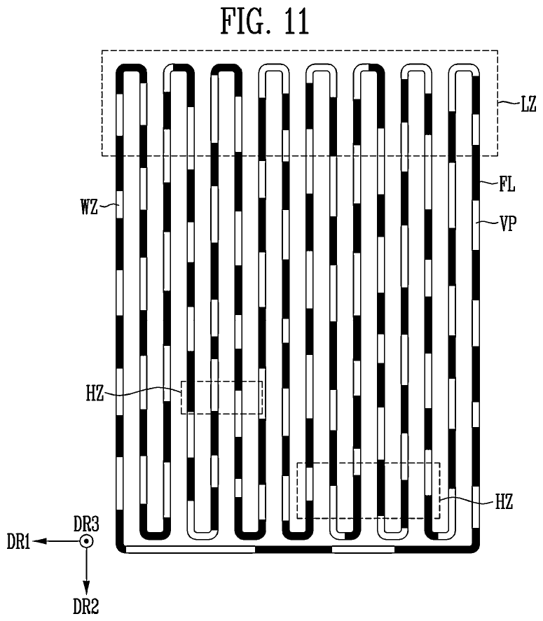

FIG. 10 is a rear perspective view of the heat dissipation module 240 in accordance with embodiments of the present disclosure. FIG. 11 is a diagram for describing performance of heat dissipation in the heat dissipation module 240 in accordance with embodiments of the present disclosure.

Referring to FIG. 10, there is an illustration of a rear view of the heat dissipation module 240 of FIG. 7, and the representation of the second surface SF2 is omitted to effectively illustrate the arrangement of the partition wall PW in the heat dissipation module 240.

The partition wall PW may forma a closed loop. The aforementioned liquid FL (refer to FIG. 9) may be contained in the closed loop. In an embodiment, the partition wall PW may further include an opening (not illustrated) to allow the liquid FL to be injected into a space formed by the closed loop in the partition wall PW. In an embodiment, during a process of fabricating the partition wall PW (or the heat dissipation module 240), the liquid FL may be injected into a space formed by the closed loop in the partition wall PW. After injecting the liquid FL, the opening to allow the liquid FL to be injected into the space formed by the closed loop in the partition wall may be sealed. In this case, the partition wall PW may have no opening.

Referring to FIG. 10, there is illustrated an embodiment in which the heat dissipation module 240 includes only one closed loop defined by the partitioned wall PW. However, embodiments of the present disclosure are not limited to the foregoing structure. For example, two or more closed loops may be included in the heat dissipation module 240.

Two or more closed loops may be placed on a plane defined by the first direction DR1 and the second direction DR2. The two or more closed loops, for example, may be arranged parallel to each other in the first direction DR1 or the second direction DR2, and embodiments of the present disclosure are not limited thereto.

Referring to FIGS. 10 and 11, a high-temperature area HZ and a low-temperature area LZ may be defined in the heat dissipation module 240. Referring also to FIG. 2, the high-temperature area HZ (or high-temperature zone HZ) and the low-temperature area LZ (or low-temperature zone LZ) may be defined in the electronic device 100 in response to the surrounding temperature of the heat dissipation module 240. The high-temperature area HZ and the low-temperature area LZ in the heat dissipation module 240 may be adaptively variable and may not be predefined areas. The high-temperature area HZ may be an area positioned to overlap the data driver 220 (e.g., the data driving integrated circuit D-IC). The high-temperature area HZ, for example, may be an area overlapping the display panel 210 that displays the image IM (refer to FIG. 1) with high-luminance. The low-temperature area LZ, for example, may be an area distant from the data driver 220 (e.g., referring to FIG. 2, an area of an end of the display panel 210 opposite to the second direction DR2). However, it should be noted that the high-temperature area HZ and the low-temperature area LZ are relatively defined, and embodiments of the present disclosure are not limited to the aforementioned example.

Referring to FIG. 11, the working fluid WZ may include liquid FL and an air layer VP. The air layer VP (e.g., a vapor) may increase in volume in the high-temperature area HZ, and decrease in volume in the low-temperature area LZ. If the volume of the air layer VP increases in the high-temperature area HZ, the air layer VP may displace the liquid FL. The liquid FL that is displaced from the high-temperature area HZ by the air layer VP may move into the low-temperature area LZ. In the low-temperature area LZ, the liquid FL releases heat. Thereby, the heat dissipation module 240 (refer to FIG. 10) may perform the heat dissipation function.

The volume of the air layer VP (or the volume of the liquid FL) in the working fluid WZ may be designed without restriction within a range that allows the movement of the liquid FL through the capillary phenomenon according to the design of those skilled in the art. For example, the volume of the liquid FL in the working fluid WZ may be approximately 20% or more and be less than 100%. For example, the volume of the liquid FL in the working fluid WZ may be approximately 50%.

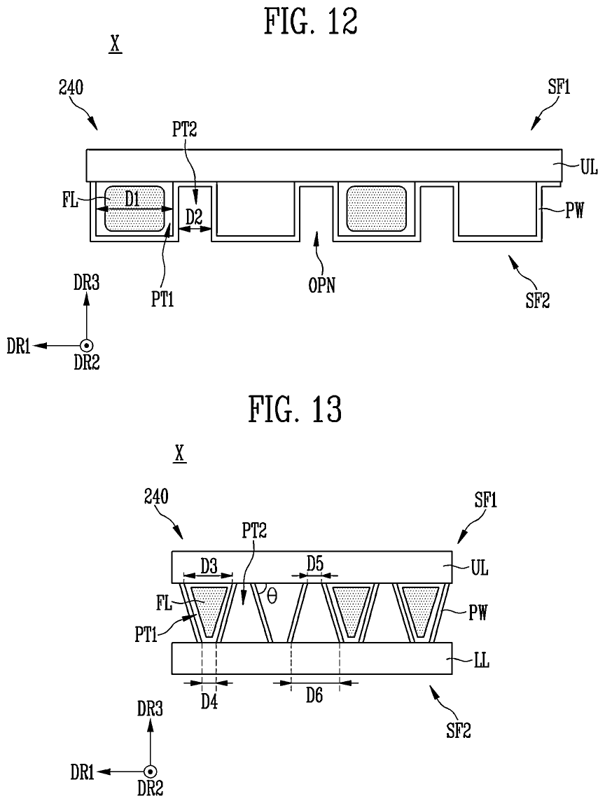

FIG. 12 is a sectional view illustrating area X in another embodiment of the heat dissipation module 240 of FIG. 7.

Referring to FIG. 12, in the dissipation module 240 in accordance with embodiments of the present disclosure, a second planar component LL (refer to FIG. 9) may be omitted. Therefore, the second path PT2 may include an opening OPN, and may be connected to the outside of the heat dissipation module 240 in the opening OPN. External air of the heat dissipation module 240 may be easily flown though the second path PT2 through the opening OPN. Hence, heat exchange between the liquid FL in the first path TP1 and the external gas in the second path PT2 may be more easily performed. Accordingly, the heat dissipation effect of the heat dissipation module 240 may be enhanced.

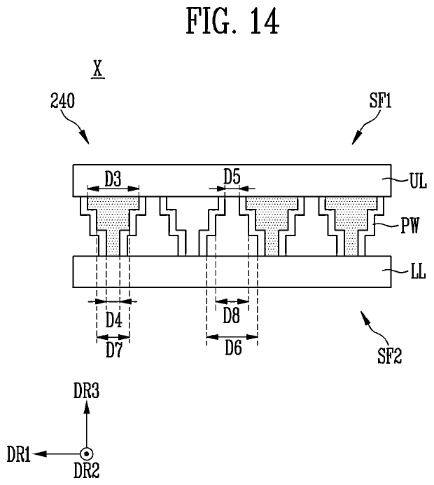

FIG. 13 is a sectional view illustrating area X in another embodiment of the heat dissipation module 240 of FIG. 7.

Referring to FIG. 13, a certain inclined angle θ may be formed between the partition wall PW and the first surface SF1. For example, the first path PT1 may have a width of a third dimension D3 on a side thereof adjacent to the first surface SF1, and may have a width of a fourth dimension D4 different from the third dimension D3 on a side thereof adjacent to the second surface SF2. For example, the second path PT2 may have a width of a fifth dimension D5 on a side thereof adjacent to the first surface SF1, and may have a width of a sixth dimension D6 different from the fifth dimension D5 on a side thereof adjacent to the second surface SF2.

In an embodiment, the certain inclined angle θ may be an acute angle less than the right angle (90°). For example, in an area corresponding to the first path PT1, the inclined angle θ between the partition wall PW and the first surface SF1 may be an acute angle. In the aforementioned embodiment, the third dimension D3 may be greater than the fourth dimension D4. The fifth dimension D5 may be less than the sixth dimension D6. In the aforementioned embodiment, the liquid FL may have a relatively larger contact area with an area of the first planar component UL where heat is introduced. Furthermore, as a result of the diagonal arrangement of the partition wall PW, a surface area with which the liquid FL contacts the second path PT2 may be relatively increased. Consequently, the heat dissipation effect of the heat dissipation module 240 in accordance with embodiments of the present disclosure may be enhanced.

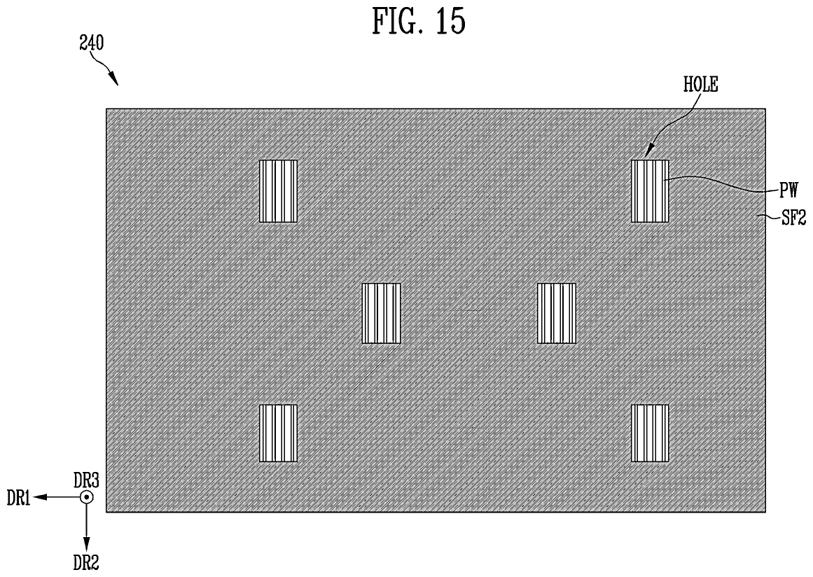

FIG. 14 is a sectional view illustrating area X in another embodiment of the heat dissipation module 240 of FIG. 7.

Referring to FIG. 14, there is illustrated an embodiment where the partition wall PW includes one or more stepped portions. For example, the first path PT1 may have a width of a third dimension D3 on a side thereof adjacent to the first surface SF1, and may have a width of a fourth dimension D4 different from the third dimension D3 on a side thereof adjacent to the second surface SF2. For example, the second path PT2 may have a width of a fifth dimension D5 on a side thereof adjacent to the first surface SF1, and may have a width of a sixth dimension D6 different from the fifth dimension D5 on a side thereof adjacent to the second surface SF2.

An angle between the partition wall PW and the first surface SF1 may be the right angle, but embodiments of the present disclosure are not limited thereto. An angle between the partition wall PW and the second surface SF2 may be the right angle, but embodiments of the present disclosure are not limited thereto.

In an embodiment where the partition wall PW includes one stepped portion, the first path PT1 may have widths of the third dimension D3 and the fourth dimension D4. In the aforementioned embodiment, the second path PT2 may have widths of the fifth dimension D5 and the sixth dimension D6.

In an embodiment where the partition wall PW includes two or more stepped portions, the first path PT1 may have widths of the third dimension D3, the fourth dimension D4, and a seventh dimension D7. The seventh dimension D7 may be less than the third dimension D3 and greater than the fourth dimension D4. In the aforementioned embodiment, the second path PT2 may have widths of the fifth dimension D5, the sixth dimension D6, and an eighth dimension D8. The eighth dimension D8 may be greater than the fifth dimension D5 and less than the sixth dimension D6.

In an embodiment where the partition wall PW include two or more stepped portions, a surface area with which the liquid FL flowing through the first path PT1 contacts the second path PT2 through the partition wall PW may be increased. Therefore, the heat dissipation effect may be enhanced.

FIG. 15 is a rear view of a heat dissipation module 240 according to other embodiments of the present disclosure.

Referring to FIG. 15, in the dissipation module 240 in accordance with embodiments of the present disclosure, a hole HOLE may be formed in the second planar component LL. The hole HOLE may expose at least a portion of the partition wall PW to the outside of the heat dissipation module 240. The hole HOLE may expose at least a portion of the partition wall PW in an area corresponding to an area in which heat dissipation in the display module DM is higher than other areas.

In an embodiment, the second planar component LL may include a plurality of holes HOLE. The holes HOLE, for example, may be positioned adjacent to each other in the first direction DR1, or may be positioned adjacent to each other in the second direction DR2. However, embodiments of the present disclosure are not limited to the foregoing example.

Due to the hole HOLE, a surface area with which the partition wall PW contacts external air of the heat dissipation module 240 may increase, whereby the heat dissipation effect can be enhanced.

A heat dissipation module and an electronic device including the heat dissipation module in accordance with embodiments of the present disclosure may be improved in heat dissipation efficiency.

Although the preferred embodiments of the present disclosure have been disclosed for illustrative purposes, those skilled in the art will appreciate that various modifications, additions and substitutions are possible, without departing from the scope and spirit of the present disclosure as disclosed in the accompanying claims. Accordingly, the bounds and scope of the present disclosure should be determined by the technical spirit of the following claims.

What is claimed is:

1. A heat dissipation module comprising:
a first planar component;
a partition wall coupled to the first planer component and defining a first path having one side closed by the first planer component, the first path forming a closed loop; and
working fluid disposed in the first path.

2. The heat dissipation module according to claim 1, further comprising a second planar component coupled to the partition wall with the partition wall disposed between the first planar component and the second planar component, and defining a second path disposed between the partition wall and the second planar component,
wherein the second path communicates with an outside of the heat dissipation module.

3. The heat dissipation module according to claim 2, wherein the first planar component includes a first surface and the second planar component includes a second surface.

4. The heat dissipation module according to claim 2,
wherein the partition wall is disposed to be inclined with respect to the first surface and the second surface,
wherein the first path has a width of a third dimension disposed adjacent to the first surface and has a width of a fourth dimension less than the third dimension and disposed adjacent to the second surface, and
wherein the second path has a width of a fifth dimension disposed adjacent to the first surface and has a width of a sixth dimension greater than the fifth dimension and disposed adjacent to the second surface.

5. The heat dissipation module according to claim 4, wherein an inclined angle formed between the partition and the first surface in an area corresponding to the first path is an acute angle.

6. The heat dissipation module according to claim 5,
wherein the partition wall includes at least two stepped portions,
wherein the first path has a width of a seventh dimension disposed between the first surface and the second surface and the seventh dimension is less than the third dimension and greater than the fourth dimension, and
wherein the second path has a width of an eighth dimension disposed between the first surface and the second surface and the eighth dimension is greater than the fifth dimension and less than the sixth dimension.

7. The heat dissipation module according to claim 2, wherein the partition wall includes an opening in an area facing away from the first planar component and the second path communicates with the outside of the heat dissipation module through the opening.

8. The heat dissipation module according to claim 2, wherein the first path has a width of a first dimension and the second path has a width of a second dimension less than the first dimension.

9. The heat dissipation module according to claim 2, wherein the first planar component includes a first surface, and the second planar component includes a second surface,
wherein the partition wall includes one or more stepped portions,
wherein the first path has a width of a third dimension disposed adjacent to the first surface and has a width of a fourth dimension less than the third dimension and disposed adjacent to the second surface, and
wherein the second path has a width of a fifth dimension disposed adjacent to the first surface and has a width of a sixth dimension less than the fifth dimension and disposed adjacent to the second surface.

10. The heat dissipation module according to claim 1, wherein the working fluid includes liquid and an air layer.

11. The heat dissipation module according to claim 10, wherein a volume of the liquid in the working fluid is 20% or more and less than 100%.

12. The heat dissipation module according to claim 1, further comprising a second planar component coupled to the partition wall and defining a second path disposed between the partition wall and the second planar component,
wherein the second planar component includes a hole that exposes at least a portion of the second path.

13. An electronic device comprising:
a display panel including a plurality of pixels arranged to display an image on a front surface of the display panel; and
a heat dissipation module disposed on a rear surface of the display panel,
wherein the heat dissipation module comprises:
a first planar component facing the rear surface of the display panel;
a partition wall coupled to the first planar component and defining a first path one side of which is closed by the first planar component, and a second path spaced apart from the first path and communicating with an outside of the dissipation module, the first path forming a closed loop; and
working fluid disposed in the first path.

14. The electronic device according to claim 13, further comprising an adhesive component attached to the rear surface of the display panel, and configured to attach the rear surface of the display panel to the first planar component of the heat dissipation module.

15. The electronic device according to claim 13, wherein the first planar component includes a first surface connected to the partition wall and the second planar component including a second surface connected to the partition wall.

16. The electronic device according to claim 15,
wherein the partition wall is disposed to be inclined with respect to the first surface and the second surface,
wherein the first path has a width of a third dimension disposed adjacent to the first surface and has a width of a fourth dimension less than the third dimension and disposed adjacent to the second surface, and
wherein the second path has a width of a fifth dimension disposed adjacent to the first surface and has a width of a sixth dimension greater than the fifth dimension and disposed adjacent to the second surface.

17. The electronic device according to claim 15,
wherein the partition wall includes at least one stepped portions,
wherein the first path has a width of a third dimension disposed adjacent to the first surface and has a width of a fourth dimension less than the third dimension and disposed adjacent to the second surface, and
wherein the second path has a width of a fifth dimension disposed adjacent to the first surface and has a width of a sixth dimension greater than the fifth dimension and disposed adjacent to the second surface.

18. The electronic device according to claim 15, wherein the partition wall includes an opening in an area facing away from the first planar surface and the opening connects the second path to the outside of the heat dissipation module.

19. The electronic device according to claim 13, wherein the first path has a width of a first dimension and the second path has a width of a second dimension less than the first dimension.

20. The electronic device according to claim 13, further comprising a second planar component facing the first planar component with the partition wall disposed between the first planar component and the second planar component,
wherein the second planar component includes a hole that exposes at least a portion of the second path.
